(19) United States
(12) Patent Application Publication
(10) Pub. No.: US 2007/0045642 A1
(43) Pub. Date: Mar. 1, 2007

(54) Solid-state imager and formation method using anti-reflective film for optical crosstalk reduction

(75) Inventor: Jiutao Li, Boise, ID (US)

Correspondence Address: DICKSTEIN SHAPIRO LLP, 1825 EYE STREET, NW, WASHINGTON, DC, 20006, US

(73) Assignee: Micron Technology, Inc.

(21) Appl. No.: 11/210,969

(22) Filed: Aug. 25, 2005

(51) Int. Cl. H01L 33/00

(52) U.S. Cl. 257/98

(57) ABSTRACT

Conductive lines in an imaging device are coated with an anti-reflective film to reduce crosstalk caused by light reflecting from the conductive lines. An interface results between the anti-reflective film and the surface of the conductive line surface. A second interface exists between the anti-reflective film and an overlying insulating layer. The anti-reflective film is formed from a material having a complex refractive index such that reflectance is reduced at each of the two interfaces. The anti-reflective film also can be light absorbing to provide further reductions in light reflection and consequent crosstalk.

### BACKGROUND OF THE INVENTION

1. Field of the Invention

The invention relates generally to semiconductor imaging devices and in particular to a semiconductor-based imaging device having structures for reducing optical crosstalk among pixels.

2. Discussion of Related Art

Semiconductor imaging devices include charge coupled devices (CCDs), photodiode arrays, charge injection devices, and hybrid focal plane arrays. CCDs are often employed for image acquisition and enjoy a number of advantages which makes it the incumbent technology, particularly for small-size imaging applications. CCDs are also capable of large formats with small pixel-size and they employ low-noise charge-domain processing techniques.

Inherent limitations in CCD technology have promoted interest in CMOS imagers for possible use as a low-cost imaging-device alternative. Advantages of CMOS imagers over CCD imagers include low-voltage operation and low power-consumption. Also, CMOS imagers are compatible with integrated on-chip electronics (control logic and timing, image processing, and signal conditioning such as analog-to-digital conversion). CMOS imagers also enjoy lower fabrication costs as compared with the conventional CCD imagers because standard CMOS processing-techniques can be used.

CMOS imagers of the type discussed above are generally known as discussed, for example, in Nixon et al., “256×256 CMOS Active Pixel Sensor Camera-on-a-Chip,” IEEE Journal of Solid-State Circuits, Vol. 31(12) pp. 2046-2050, 1996; and Mendis et al, “CMOS Active Pixel Image Sensors,” IEEE Transactions on Electron Devices, Vol. 41(3) pp. 452-453, 1994, the entireties of which are incorporated by reference. CMOS imaging circuits, processing steps thereof, and detailed descriptions of the functions of various CMOS elements of an imaging circuit are described, for example, in U.S. Pat. No. 6,140,630 to Rhodes, U.S. Pat. No. 6,376,868 to Rhodes, U.S. Pat. No. 6,333,205 to Rhodes, U.S. Pat. No. 6,326,652 to Rhodes, U.S. Pat. No. 6,310,366 to Rhodes et al., and U.S. Pat. No. 6,204,524 to Rhodes, the entire disclosures of which are incorporated by reference.

Solid-state imagers, including CCD, CMOS, and others discussed above, employ optical photon-sensor devices which are subject to optical crosstalk. Optical crosstalk occurs when light that is expected to strike a pixel is misdirected and instead strikes a neighboring pixel. The misdirection often comes from reflections within the pixel structure.

Solid-state imagers often use common (e.g., aluminum) metal lines at upper layers of an imager integrated circuit to conduct electrical power and signals. From an optical performance perspective, however, aluminum disadvantageously exhibits very high light reflection.

FIG. 1 is a simplified schematic illustration of light reflection within an imager and attendant crosstalk problems. FIG. 1 shows a cross-section of a portion of an imager having two adjacent imager pixels 1, 2. Although the imager shown is a CMOS imager, FIG. 1 represents optical crosstalk occurring in other solid state imagers as well. Pixels 1, 2 are representative of a plurality of pixels making up a pixel array in the imager. Fundamental features of the pixels 1, 2, shown simplified in FIG. 1, include respective photodiode photosensors 3, 4, which collect photons and convert them to photo-charges. Conductive metal lines 5, 6, 7 are located in an upper portion of the imager integrated circuit. Additional layers 8 disposed above the metal lines 5, 6, 7 include, for example, an insulating layer (SiO2) and a color filter array above the insulating layer. Respective microlenses 9, 10 focus in-coming light on the photodiode photosensors 3, 4.

FIG. 1 illustrates a path that photons 11, 12 might take to the pixels 1, 2. Photon 11 enters microlens 9, designated as a red pixel, for example, by the color filter array in layer 8. Instead of being focused on photosensor 3, however, photon 11 is refracted by microlens 9 and reflected from conductive metal line 5 in an upper metallization layer, here metal layer three, such that photon 11 strikes photosensor 4 of pixel 2, which has been designated as a green pixel, for example. As a result of photon 11 striking photosensor 4 instead of photosensor 3 (i.e., crosstalk), electric charge that should have accumulated at photosensor 3 accumulates instead at photosensor 4. Thus, instead of generating a red signal for that portion of the image, the signal generated is green, and the resulting photo-image contains inaccuracies.

The state of the art would be improved by reducing the amount of light that reflects from metal lines in the metallization layers used to conduct electrical power and signals in imagers. Common anti-reflection solutions are difficult to implement in current fabrication processes due to several factors, including: (1) solid state imagers operate across a wide visible-light spectrum, and interference-based anti-reflective coatings are effective within only a narrow range of wavelengths; (2) dark or black-colored non-conductive coating materials have poor photon absorption, so a very thick application of the coating material normally is required: tight spaces and close tolerances within the imager would not allow for added layers several microns thick; (3) reflections can be reduced by surface-roughness that can scatter and absorb light, however, the dimensional-scale of the roughness should be at least the same order of incident wavelength (typically half-micrometer for visible light): surface features of this size are too large for an imager to contain; and (4) higher-conductance materials (such as Al, Ag) have correspondingly higher electron densities, so these materials are more efficient photon-absorbers: higher electron density, however, also corresponds to higher undesirable reflection.

Accordingly, there is a need and a desire to provide anti-reflective properties to the conductive lines in solid-state imagers to mitigate optical crosstalk.

### BRIEF SUMMARY OF THE INVENTION

In an exemplary embodiment of the invention, pixel arrays with conductive lines having reflecting surfaces with the potential to produce optical crosstalk in pixel circuits are coated with an anti-reflective film. The anti-reflective film is disposed between the reflecting surface and an over-lying insulating layer to produce a first interface between the anti-reflective film and the insulating layer, and a second interface between the anti-reflective film and the reflecting surface. Total reflectance is reduced at each of the two interfaces. In addition, the anti-reflective film absorbs light. The reduction in reflectance and the light-absorption combine to mitigate optical crosstalk. One exemplary anti-reflective film material is the refractory metal tantalum. Anti-reflective tantalum films mitigate photons reflecting off of aluminum conductor lines and onto photosensors of neighboring pixels.

### BRIEF DESCRIPTION OF THE DRAWINGS

The above and other advantages and features of the invention will be more clearly understood from the following detailed description which is provided in connection with the accompanying drawings.

FIG. 1 is an illustration of crosstalk caused by light reflected from metal lines in a CMOS imager;

FIG. 2 is a cross-section of a portion of an array of CMOS imager pixels featuring anti-reflective films according to an exemplary embodiment of the invention;

FIG. 3 illustrates the light-reflecting properties of a generalized metal-stack structure according to an exemplary embodiment of the invention;

FIG. 4 is a graphical illustration of optical properties (reflection and transmission) of a variety of specific metal-stack structures based on the generalized structure of FIG. 3;

FIG. 5 is a cross-section illustrating steps in the fabrication of an anti-reflective conductive-line structure according to an exemplary embodiment of the invention;

FIG. 6 is a cross-section illustrating further steps in the fabrication of an anti-reflective conductive-line structure according to an exemplary embodiment of the invention;

FIG. 7 is a cross-section illustrating additional steps in the fabrication of an anti-reflective conductive-line structure according to an exemplary embodiment of the invention;

FIG. 8 is a cross-section illustrating additional steps in the fabrication of an anti-reflective conductive-line structure according to an exemplary embodiment of the invention;

FIG. 9 is a cross-section illustrating an alternative method for fabrication of an anti-reflective conductive-line structure according to an exemplary embodiment of the invention;

FIG. 10 is a cross-section illustrating further steps in the alternative method for fabrication of an anti-reflective conductive-line structure according to an exemplary embodiment of the invention;

FIG. 11 is a cross-section illustrating additional steps in the alternative method for fabrication of an anti-reflective conductive-line structure according to an exemplary embodiment of the invention;

FIG. 12 is a cross-section illustrating additional steps in the alternative method for fabrication of an anti-reflective conductive-line structure according to an exemplary embodiment of the invention;

FIG. 13 illustrates an array of CMOS imager pixels constructed in accordance with an exemplary embodiment of the invention; and

FIG. 14 illustrates a system including an imaging device provided with the imager array of FIG. 13.

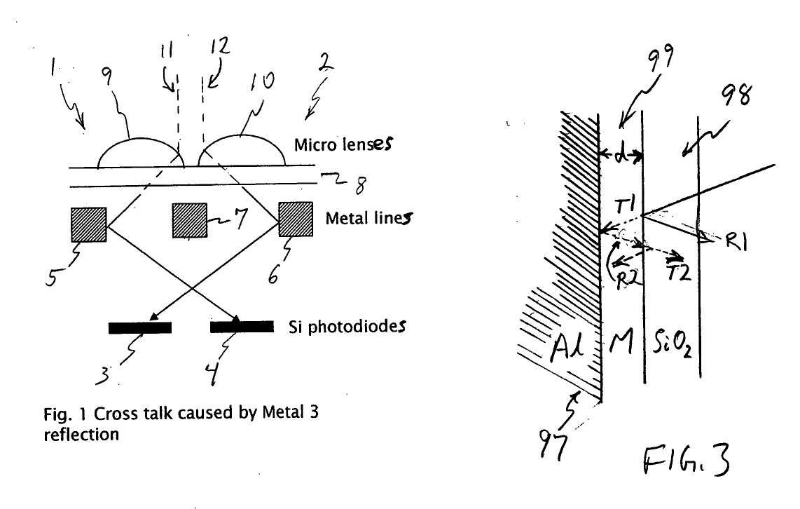

### DETAILED DESCRIPTION OF THE INVENTION

In the following detailed description, reference is made to the accompanying drawings which form a part hereof and illustrate specific exemplary embodiments by which the invention may be practiced. It should be understood that like reference numerals represent like elements throughout the drawings. These embodiments are described in sufficient detail to enable those skilled in the art to practice the invention. It is to be understood that other embodiments may be utilized, and that structural, logical, and electrical changes may be made without departing from the spirit and scope of the invention.

The term “substrate” is to be understood as including silicon, silicon-on-insulator (SOI), or silicon-on-sapphire (SOS) technology, doped and undoped semiconductors, epitaxial layers of silicon supported by a base semiconductor foundation, and other semiconductor structures. Furthermore, when reference is made to a “substrate” in the following description, previous process steps may have been utilized to form regions or junctions in or over the base semiconductor structure or foundation. In addition, the semiconductor need not be silicon-based, but could be based on silicon-germanium, germanium, or gallium arsenide, for example.

The term “light” refers to electromagnetic radiation that can produce a visual sensation (visible light) as well as electromagnetic radiation outside of the visible spectrum. In general, light as used herein is not limited to visible radiation, but refers more broadly to the entire electromagnetic spectrum, particularly electromagnetic radiation that can be transduced by a solid state photosensor into a useful electrical signal.

The terms “pixel” or “pixel cell” refer to a picture element unit containing circuitry including a photosensor and transistors for, in the case of an image sensor, converting incident electromagnetic radiation to an electrical signal. For purposes of illustration, representative pixels are illustrated in the drawings and description herein. Typically fabrication of all pixels in an imager will proceed simultaneously in a similar fashion. The following detailed description is, therefore, not to be taken in a limiting sense, and the scope of the invention is defined by the appended claims.

Referring to FIG. 2, a portion of a CMOS imager array is shown in cross-section to reveal pixel-constructs according to an exemplary embodiment of the invention. Although the invention is described with reference to a CMOS imager array, it also can be applied to other solid state imager arrays, as well as to display devices. Accordingly, the description which follows is only exemplary of the environment in which the invention may be used.

FIG. 2 shows a portion of CMOS pixel 13 and portions of adjacent pixels on either side of pixel 13 exemplifying an embodiment of the invention. The pixel portion shown is part of a four transistor (4T) pixel, though the pixels may have any of several circuit configurations. Representative pixel 13 of the exemplary CMOS imager array includes a photodiode photosensor 14 formed in an epitaxial (EPI) p-type layer 16, which is formed over a p-type substrate 17. An n-type accumulation region 18 is provided in EPI layer 16 and accumulates photo-generated charge produced from photons striking the photodiode photosensor 14. An uppermost p-type surface region 20 is provided over the n-type accumulation region 18. The pixel 13 further includes a doped p-well 22 defined in the EPI layer 16. An identical p-well 23 is also provided in EPI layer 16 as part of an adjacent pixel. A transfer gate 24 is formed above a portion of p-well 22 and adjacent the photodiode photosensor 14. The transfer gate 24 serves as part of a transfer transistor for electrically-gating charges accumulated by photodiode photosensor 14 to floating diffusion region 26 implanted in a portion of p-well 22.

A reset gate 28 is formed as part of a reset transistor next to the transfer gate 24. The reset transistor is connected to a voltage source (e.g., V_{dd}) through a source/drain region and functions to provide a resetting-voltage to the floating diffusion region 26. Lateral isolation between the adjacent pixels on either side of pixel 13, is provided by shallow trench isolation (STI) regions 42, 44.

A gate oxide layer 46 and a polysilicon layer 48 are formed on or near the upper surface of the EPI layer 16. In an exemplary embodiment, the gate oxide layer 46 is deposited over the entire upper surface of the EPI layer 16, followed by the deposition of the polysilicon layer 48. The polysilicon layer 48 can be undoped, doped in situ, or subsequently implanted with a dopant, for example. An insulative capping layer 50 (made of, e.g., tetraethyl orthosilicate (TEOS), Si(OC2H5)4, oxide, or nitride) is fabricated over the polysilicon layer 48. Formation of the insulative capping layer 50 can optionally be preceded in another exemplary embodiment by a silicide layer 52. These layers 46, 48, 50, (optional 52), are then masked with a patterned photoresist and etched to form the structures shown in FIG. 2.

A conductor 36 is in electrical communication with the floating diffusion region 26, as well as a gate of a source-follower transistor (not shown). Conductor 36 routes through a conductive path in an interconnect layer 40 (e.g., an M1 metal layer) and connects to other conductors up through interconnect layer 94 (e.g., an M2 metal layer), semiconductor layer 96, and ultimately conductor 97 in interconnect layer 98 (e.g., an M3 metal layer).

Anti-reflective film 99 is shown on surfaces of opposite vertical sides of conductor 97. Anti-reflective film 99 prevents photons that enter pixel 13 through microlens 108 and color filter array 106, intended to strike photodiode photosensor 14, from errantly reflecting to an adjacent pixel and striking a photosensor of a neighboring pixel. Most such optical crosstalk is the result of photons reflecting from the vertical-side surfaces of conductors. Consequently, the anti-reflective film 99 is most effective in preventing crosstalk when coated on the vertical side surfaces of the conductor 97.

The anti-reflective film 99 also can be coated, however, on other sides of the conductor 97, including the top, the bottom, or both (i.e., encasing the conductor 97). Coating the top and/or bottom side surfaces of the conductor 97 is not necessarily required in order to reduce optical crosstalk, but rather for a more economical fabrication process. Providing a bottom coating, or leaving a top coating in place, for example, may mean that an extra patterning or etching step is not needed. Consequently, a more-economical fabrication process results.

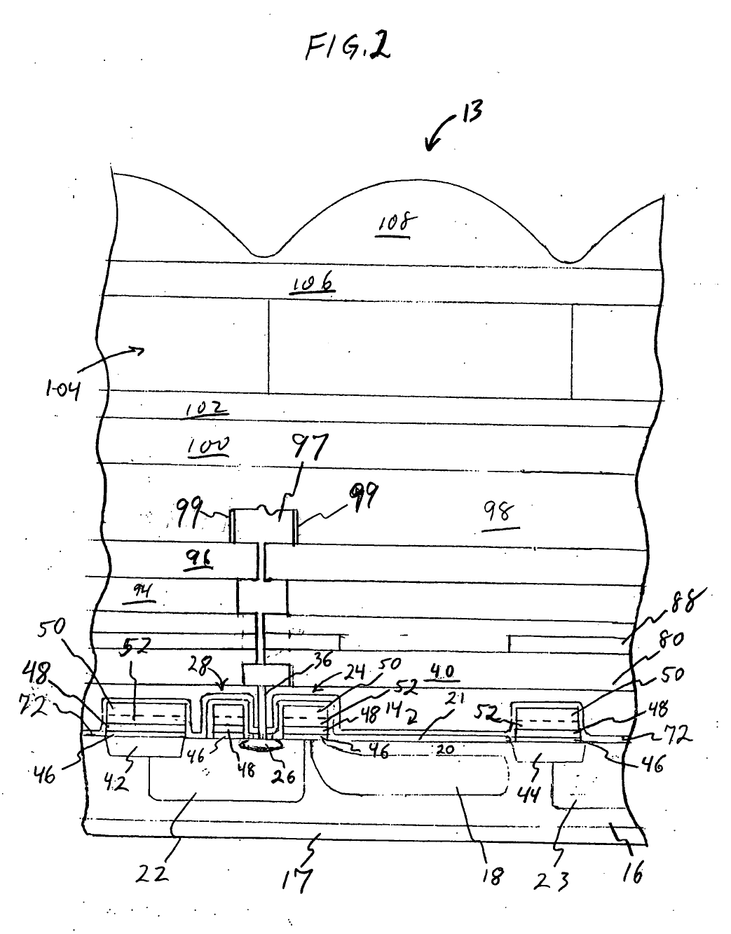

Characteristics of anti-reflective film 99 are now described in greater detail with reference to FIG. 3, which illustrates a generalized construction of an aluminum (Al) conductor, e.g., conductor 97, coated on a vertical-side surface with anti-reflective film 99. An insulating (SiO2) layer 98 (e.g., the M3 dielectric layer) is deposited on the anti-reflective film 99. It should be understood that although the description relates to applying anti-reflective film 99 to conductors in the M3 dielectric layer, the invention is not so limited. Other reflective surfaces can be coated with the anti-reflective film 99, including conductors 97 in the M2 and M1 layers (closer to the photosensor layer). As the size of the conductors 97 decreases and the depth within the pixel increases, the cost of providing the anti-reflective may outweigh the improvement in optical crosstalk, however.

The arrows in FIG. 3 represent paths taken by photons that are transmitted and reflected by a vertical-side surface of the conductor 97 coated with the anti-reflective film 99. The SiO2 insulating layer 98 is deposited on the anti-reflective film 99. It should be noted that although aluminum is discussed as a common conductor material, various combinations of conductive metal 97 and anti-reflective film 99 can be used.

Reflective and transmissive properties of the combination of layers 97, 98, 99 can be quantified by considering the various light paths that photons will take. Path R1 represents the portion of incoming light that is reflected at the M/SiO2 interface, (i.e., the layers 99/98 interface) where M represents the anti-reflective film. T1 is the portion of incoming light that is un-reflected and transmits into the M layer. R2 represents reflection of the light T1 at the M/Al interface (i.e., the layers 99/97 interface). T2 represents transmission of reflected light R2 beyond the M/SiO2 interface.

Equation 1 represents the total reflection of the layers 97, 98, 99 based on the light paths above and taking into account the anti-reflective film 99 thickness d and an absorption coefficient α for the anti-reflective film 99:
R=R1+(1−R1)²*exp(−2αd)*R2 (1)
Without anti-reflective treatment, aluminum exhibits a very high reflectance value R (i.e., the ratio of the energy of reflected to incident light from a dielectric). For aluminum, R is 0.89 @ 516 nm. Adding a thin layer of anti-reflective film 99 reduces the total reflectance R. Anti-reflective film 99 is selected taking into account the material's complex refractive index. The anti-reflective film 99 material is selected such that the reduction in reflectance provided is effective at submicron dimensions.

Adding the anti-reflective film 99 between the aluminum and the SiO2 layers serves two purposes. The anti-reflective film 99 reduces the reflectance R of the conductor surfaces, as discussed above and more specifically below. The lower reflectance R results in less optical crosstalk in imagers that utilize aluminum conductors due to the decrease in the number of photons that will reflect off of the aluminum conductors from one pixel onto the photosensor of a neighboring pixel. In addition, anti-reflective film 99 serves to absorb light photons, thus further reducing the light intensity at the M/Al interface (FIG. 3).

In order to determine the total reflection provided by the layers 97, 98, 99 it is necessary to evaluate reflection at each of the interfaces, i.e., the M/SiO2 interface, and the M/Al interface, plus light absorption (or transmission) in the anti-reflective film 99. Light reflection at the interface of two different materials can be represented by Equation 2 as follows:

$$R = \frac{{( {n}_{1} - {n}_{2} )}^{2} + {( {k}_{1} - {k}_{2} )}^{2}}{{( {n}_{1} + {n}_{2} )}^{2} + {( {k}_{1} + {k}_{2} )}^{2}} \qquad ( 2 )$$

where n1+ik1 and n2+ik2 are complex refractive indices of two materials, e.g., aluminum and the anti-reflective film 99.

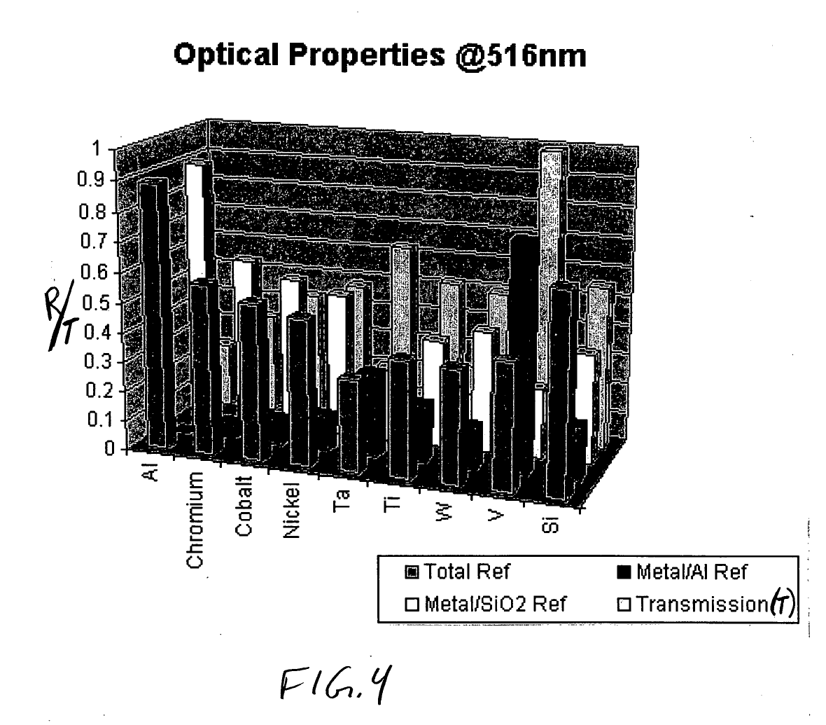

Referring to FIG. 4, optical property data is compiled for aluminum (Al) and eight elements having utility as exemplary anti-reflective films when deposited on aluminum. The optical properties were determined at a wavelength of 516 nm (blue band). The anti-reflective film was formed at a thickness of 10 nm on aluminum. Nine sets of data are shown in FIG. 4: in addition to aluminum, the eight anti-reflective film materials include the metals chromium (Cr), cobalt (Co), nickel (Ni), tantalum (Ta), titanium (Ti), tungsten (W), vanadium (V), and silicon (Si).

FIG. 4 contains four superimposed graphs, one for each of four optical properties. Beginning at the front of the graph, the first row contains total reflection data for each respective anti-reflective film disposed between aluminum and SiO2, and for aluminum/SiO2 without an intervening anti-reflective film. The second and third rows tabulate information for each anti-reflective material provided as a 10 nm film, respectively, on aluminum and under SiO2. More specifically, the second row (Metal/Al Ref) contains reflectance data for each of the eight anti-reflective films deposited as a 10 nm film on aluminum. The third row (Metal/SiO2 Ref) contains reflectance data for each of the eight metals as anti-reflective films on which SiO2 is deposited. The fourth row represents transmittance data for each of the metals alone.

It can be seen from the total reflection data (first row) that anti-reflective films made of either tantalum or titanium will reduce light reflection as compared to untreated surfaces of aluminum conductors. Simulations show that introducing a layer of approximately 10 nm tantalum (Ta) between Al and SiO2, reduces total reflection from a value of 0.89 (i.e., 89% reflectance) to 0.31 (i.e., 31% reflectance), an abatement of about three fold.

Tantalum and titanium are both compatible with the imager fabrication processes, but titanium quickly forms alloys with aluminum during higher-temperature back-end of line (BEOL) processing. Upon alloy-formation, the total reflection would increase sharply due to production of Al-dominant TiAlx (x_{—}3.0). Tantalum (Ta) is a high-melting point refractory metal, and is much less reactive than Ti. Ta also is known as a good barrier material which would slow down other metal diffusion, and has been widely studied for its barrier applications with copper (Cu), silver (Ag) metallization, and silicide formation.

Reductions of total reflection to at least about 0.50 (50% reflectance) would be considered sufficient to justify adding the anti-reflective film 99. Further reductions in total reflection, to about 0.40 (40% reflectance) and below, are achievable according to the invention. Actual reductions in reflectance will depend on the particular conductive and anti-reflective materials, and the thickness of the anti-reflective film will impact the amount of absorption that occurs. Depending on the materials, the anti-reflective films can effectively reduce reflection when deposited on reflective surfaces at thicknesses of about 5 nm, and can be deposited at thicknesses up to about 20 nm without impinging on other imager components.

Tantalum is discussed in the exemplary embodiments discussed herein due to its overall low reflectance and its low capacity to alloy with aluminum. It should be noted however that other anti-reflective film material also exhibit desirable properties and reduce total reflectance. Some of these may include the elements discussed above in connection with FIG. 4, or alloys thereof. The anti-reflective film material and thickness will be used that are most effective when combined with the particular conductor (e.g., copper and silver).and insulator making up the pixel circuitry.

Fabrication steps for forming exemplary anti-reflective films on a conductor are described below. Although the methods described utilize an aluminum conductor and a tantalum anti-reflective film, other conductors and anti-reflective films, such as those described above in connection with FIG. 4, could be used instead.

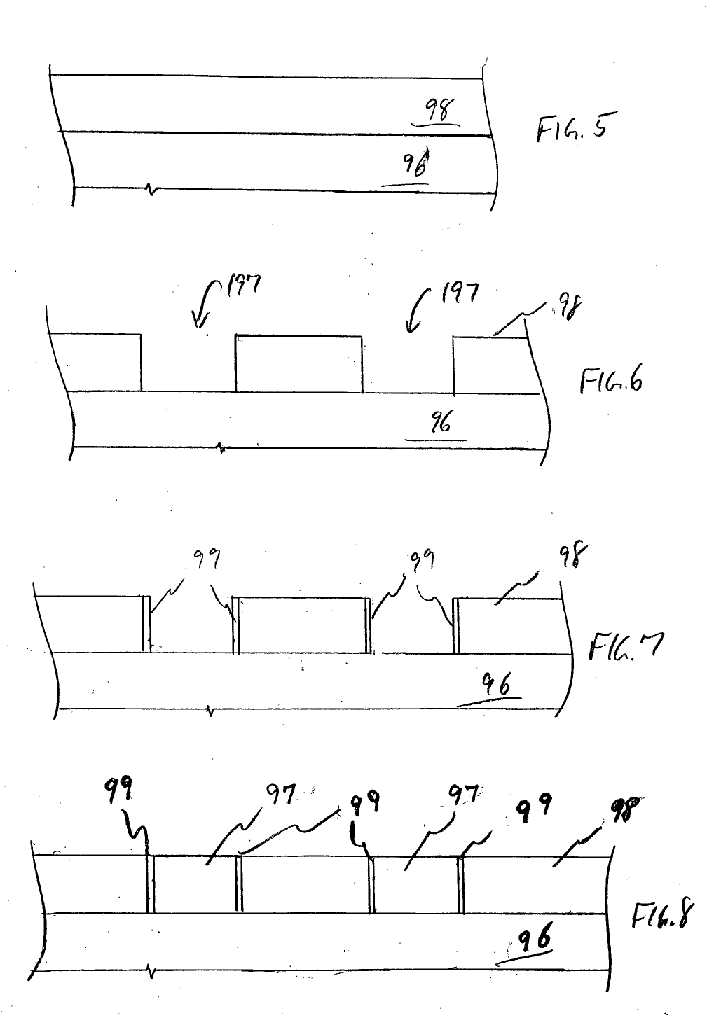

Referring to FIGS. 5-8, an exemplary method for coating an aluminum conductor with an anti-reflective film is shown. The method could be used as part of the process of forming layers 97, 98, 99 for the pixels illustrated in FIG. 2. The method utilizes known CMOS processes, and begins by depositing the insulating layer 98 (e.g., SiO2) over the semiconductor layer 96 as shown in FIG. 5. The insulating layer 98 is masked and etched to form openings 197 as shown in FIG. 6. Referring to FIG. 7, the layer of tantalum 99 is formed on the vertical sidewalls of the openings 197. The openings 197 are subsequently filled to form aluminum conductors 97 with anti-reflective film 99 on either side.

The layer of tantalum 99 also could be formed on the bottom of the openings 197, in addition to the sides, which would provide the anti-reflective film 99 on the bottom of the aluminum conductor 97. If desired, the aluminum conductor 97 could then be encased in the anti-reflective film 99 by patterning and applying a film of anti-reflective film 99 to the top of the aluminum conductors 97 after deposition of the insulating (SiO2) layer 98 and planarization.

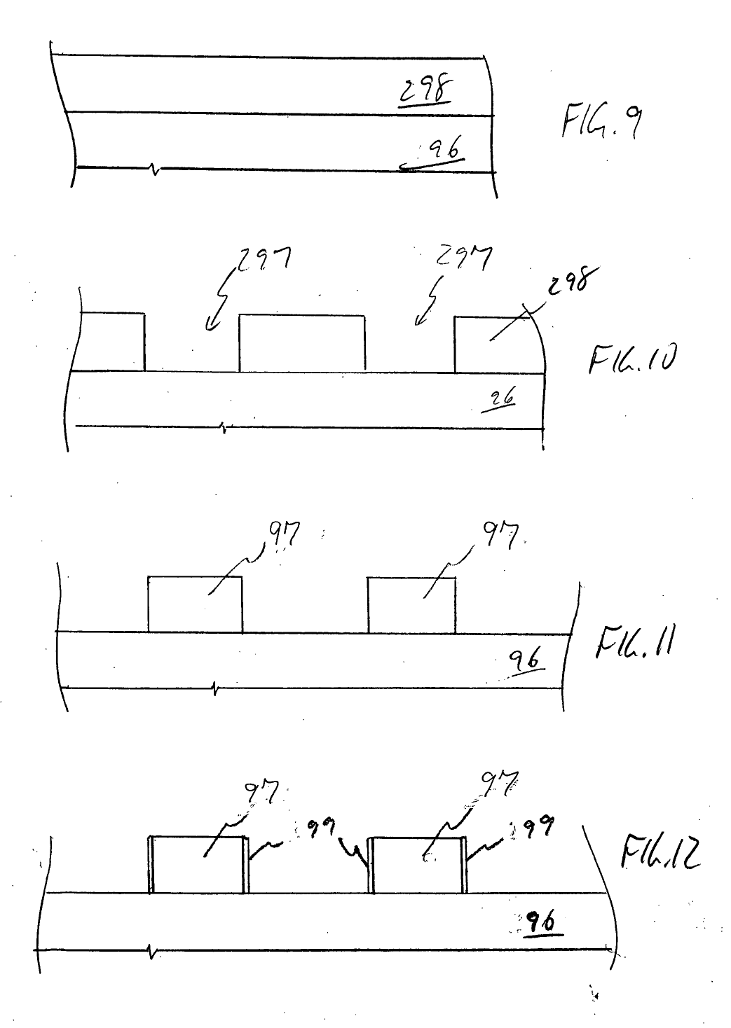

Referring to FIGS. 9-12, another exemplary method for coating an aluminum conductor is shown. The method begins with depositing a sacrificial layer 298 over semiconductor layer 96 as shown in FIG. 9. Sacrificial layer 298 is patterned and etched, for example, to form openings 297 as shown in FIG. 10. Openings 297 are filled and the sacrificial layer 298 is removed to form aluminum conductors 97, as shown in FIG. 11. Anti-reflective film 99 is shown deposited on opposing sides of conductors 300 in FIG. 12. Subsequent fabrication steps (not shown) include providing the insulating (SiO2) layer 98.

The exemplary methods above provide an anti-reflective film of tantalum on opposing vertical sides of an aluminum conductor. As noted above, other conductive and anti-reflective films can be utilized. In addition, the conductors need not be coated only on the vertical sides. The conductors also could be coated on the bottom (i.e., facing toward the photosensor) or top (i.e., facing away from the photosensor). Moreover, the conductors could be completely encased in an anti-reflective film.

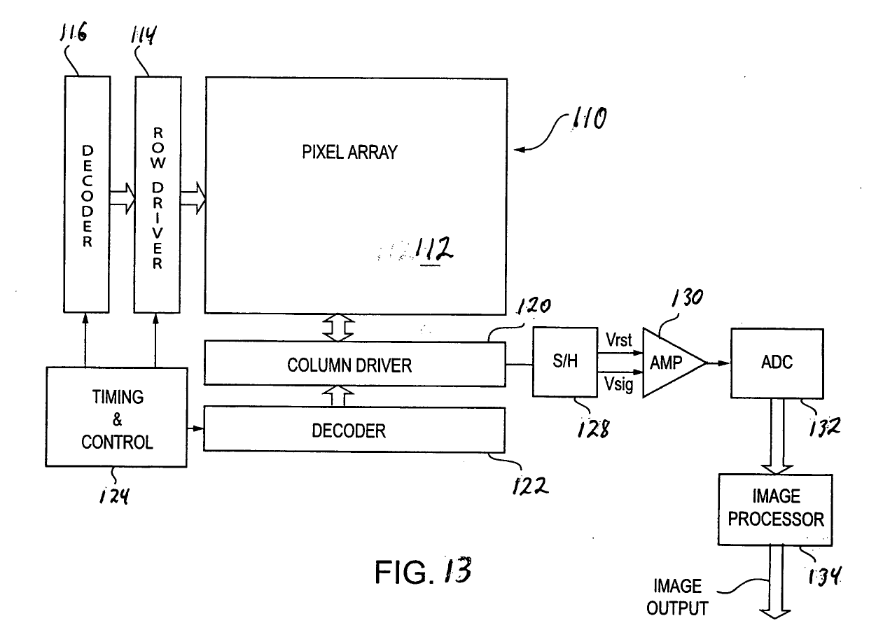

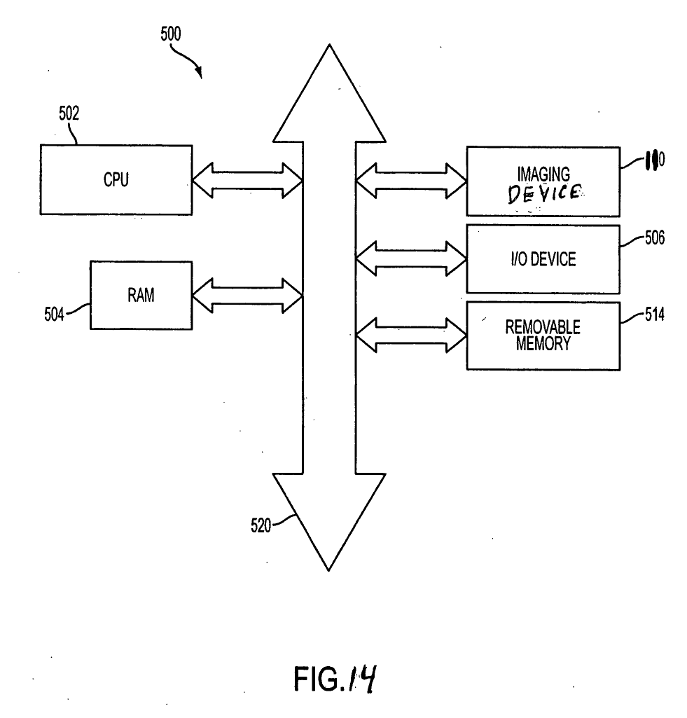

FIG. 13 illustrates an exemplary imaging device 110 that may utilize an array 112 of pixel cells 13 constructed in accordance with the invention. Pixel array 112 features a plurality of pixels arranged in columns and rows. Row lines are selectively activated by a row driver 114 in response to row address decoder 116. A column driver 120 and column address decoder 122 are also included in the imaging device 110. The imaging device 110 is operated by the timing and control circuit 124, which controls the address decoders 116, 122. The control circuit 124 also controls the row and column driver circuitry 114, 120.

A sample and hold (S/H) circuit 128 associated with the column driver 120 reads a pixel reset signal Vrst and a pixel image signal Vsig for selected pixels. A differential signal (Vrst-Vsig) is produced by differential amplifier 130 for each pixel and is digitized by analog-to-digital converter (ADC) 132. The analog-to-digital converter 132 supplies the digitized pixel signals to an image processor 134 that forms and outputs a digital image.

FIG. 14 shows a system 500, a typical processor system modified to include an imaging device 110 (FIG. 13) of the invention. The processor system 500 is exemplary of a system having digital circuits that could include imager devices. Without being limiting, such a system could include a computer system, camera system, scanner, machine vision, vehicle navigation, video phone, surveillance system, auto focus system, star tracker system, motion detection system, image stabilization system, and other systems which require an image input.

System 500, for example a camera system, generally comprises a central processing unit (CPU) 502, such as a microprocessor, that communicates with an input/output (I/O) device 506 over a bus 520. Imaging system 100 also communicates with the CPU 502 over the bus 520. The processor-based system 500 also includes random access memory (RAM) 504, and can include removable memory 514, such as flash memory, which also communicate with the CPU 502 over the bus 520. The imaging device 110 may be combined with a processor, such as a CPU, digital signal processor, or microprocessor, with or without memory storage on a single integrated circuit or on a different chip than the processor.

The processes and devices described above illustrate preferred methods and typical devices of many that could be used and produced. The above description and drawings illustrate embodiments, which achieve the objects, features, and advantages of the invention. However, it is not intended that the invention be strictly limited to the above-described and illustrated embodiments. Any modification, though presently unforeseeable, of the invention that comes within the spirit and scope of the following claims should be considered part of the invention.

What is claimed as new and desired to be protected by Letters Patent of the United States is:

1. A device comprising:
a pixel array containing a plurality of pixels, each having a pixel circuit;
conductive lines for electrically connecting with the pixel circuits; and
an anti-reflective film provided on at least portions of the conductive lines.

2. A device as in claim 1, further comprising an insulating layer provided on the anti-reflective film on a side opposite the conductive lines.

3. A device as in claim 2, wherein the insulating layer comprises SiO2.

4. A device as in claim 1, wherein the anti-reflective film is a refractory metal or an alloy of a refractory metal.

5. A device as in claim 4, wherein the refractory metal is one of tantalum and titanium.

6. A device as in claim 1, wherein the conductive lines comprise a reflective metal.

7. A device as in claim 6, wherein the reflective metal includes aluminum.

8. A device as in claim 1, wherein the pixel circuits are CMOS pixel circuits.

9. A device as in claim 1, wherein the conductive lines are provided with the anti-reflective film on at least two opposing sides.

10. A device as in claim 9, wherein the conductive lines are provided with the anti-reflective film on the two opposing sides and on at least one of a top and a bottom.

11. A device as in claim 9, wherein only two opposing sides of the conductive lines are provided with the anti-reflective film.

12. A device as in claim 1; wherein the anti-reflective film has a sub-micron thickness.

13. A device as in claim 12, wherein the thickness is less than or about 20 nm.

14. A device as in claim 12, wherein the thickness is less than or about 10 nm.

15. A device as in claim 1, wherein the anti-reflective film reduces total reflectance of the portion of the conductive lines.

16. A device as in claim 15, wherein the anti-reflective film reduces total reflectance to a value below about 0.5.

17. A device as in claim 15, wherein the anti-reflective film reduces total reflectance to a value below about 0.4.

18. A device as in claim 1, wherein the conductive lines comprise aluminum.

19. A device as in claim 1, wherein each pixel circuit comprises at least M1, M2, and M3 metallization layers, and the conductive lines are disposed in at least a selected one of the M1, M2, and M3 metallization layers.

20. A CMOS imager comprising:
a substrate; and
an array of imager pixels arranged in rows and columns on the substrate, each imager pixel comprising:
circuit elements including a photosensor arranged and configured to receive incoming light;
conductive lines electrically connecting the circuit elements; and
an anti-reflective film provided on at least portions of the conductive lines.

21. A CMOS imager as in claim 20, further comprising an insulating layer provided on the anti-reflective film on a side opposite the conductive lines.

22. A CMOS imager as in claim 21, wherein the insulating layer comprises SiO2.

23. A CMOS imager as in claim 20, wherein the anti-reflective film is a refractory metal or an alloy of a refractory metal.

24. A CMOS imager as in claim 23, wherein the refractory metal is one of tantalum and titanium.

25. A CMOS imager as in claim 20, wherein the conductive lines comprise a reflective metal.

26. A CMOS imager as in claim 25, wherein the reflective metal includes aluminum.

27. A CMOS imager as in claim 20, wherein the conductive lines are provided with the anti-reflective film on at least two opposing sides.

28. A CMOS imager as in claim 27, wherein only two opposing sides of the conductive lines are provided with the anti-reflective film.

29. A CMOS imager as in claim 20, wherein the anti-reflective film has a sub-micron thickness.

30. A CMOS imager as in claim 29, wherein the thickness is less than or about 10 nm.

31. A CMOS imager as in claim 20, wherein the anti-reflective film reduces total reflectance of the portions of the conductive lines to a value of about 0.50 or less.

32. An imager system comprising:
a processor; and
an imaging device electrically coupled to the processor, the imaging device comprising a CMOS pixel array, at least one pixel of the array comprising:
circuit elements including a photosensor arranged and configured to receive incoming light;
conductive lines electrically connecting the circuit elements; and
an anti-reflective film provided on at least portions of the conductive lines.

33. An imager as in claim 32, further comprising an insulating layer provided on the anti-reflective film on a side opposite the conductive lines.

34. An imager as in claim 33, wherein the insulating layer comprises SiO2.

35. An imager system as in claim 32, wherein the anti-reflective film is a refractory metal or an alloy of the refractory metal.

36. An imager system as in claim 35, wherein the refractory metal is one of tantalum and titanium.

37. An imager system as in claim 32, wherein the conductive lines comprise a reflective metal.

38. An imager system as in claim 37, wherein the reflective metal includes aluminum.

39. An imager system as in claim 32, wherein the conductive lines are provided on at least two opposing sides with the anti-reflective film.

40. An imager system as in claim 39, wherein only two opposing sides of the conductive lines are provided with the anti-reflective film.

41. An imager system as in claim 32, wherein the anti-reflective film has a sub-micron thickness.

42. An imager system as in claim 41, wherein the thickness is less than or about 10 nm.

43. An imager system as in claim 32, wherein the anti-reflective film reduces total reflectance of the portion of the conductive lines to a value of less than or about 0.50.

44. A method of reducing crosstalk in an imaging device comprising:
coating at least the sides of an electrically-conductive metal line with an anti-reflective film; and
depositing an insulating layer over the anti-reflective film.

45. A method as in claim 44, further comprising coating at least one of a top or bottom of the conductive metal line with the anti-reflective film.

46. A method as in claim 45, further comprising coating all sides of the conductive metal line with the anti-reflective film.

47. A method as in claim 46, wherein the coating step includes covering opposite sides of an aluminum conductor with tantalum.

48. A method as in claim 47, wherein the coating step includes depositing the tantalum to a thickness of less than or about 10 nm.

49. A conductive line construction comprising a layer of electrically insulating material, a conductive metal layer, and an anti-reflective layer between the electrically insulating layer and the conductive metal layer, the conductive line construction having lower reflectance and higher absorbance as a result of including the anti-reflective layer.

50. A conductive line construction as in claim 49, wherein the anti-reflective layer comprises a refractory metal or an alloy of the refractory metal.

51. A conductive line construction as in claim 50, wherein the anti-reflective layer comprises one of tantalum and titanium.

52. A conductive line structure as in claim 49, wherein the additional metal layer is tantalum deposited to a thickness of less than or about 10 nm.
